(19) United States
(12) Patent Application Publication
(10) Pub. No.: US 2025/0380510 A1
(43) Pub. Date: Dec. 11, 2025

(54) ACTIVE MATRIX SUBSTRATE AND DISPLAY DEVICE

(71) Applicant: Sharp Display Technology Corporation, Kameyama City (JP)

(72) Inventors: Masahiko Suzuki, Kameyama City (JP); Tetsuo Kikuchi, Kameyama City (JP); Setsuji Nishimiya, Kameyama City (JP); Hitoshi Takahata, Kameyama City (JP); Tohru Daitoh, Kameyama City (JP)

(21) Appl. No.: 19/207,641

(22) Filed: May 14, 2025

(30) Foreign Application Priority Data
Jun. 5, 2024 (JP) 2024-091803

(51) Int. Cl. H10D 86/40; H10D 86/60

(52) U.S. Cl. CPC H10D 86/423; H10D 86/431; H10D 86/441; H10D 86/60

(57) ABSTRACT

An active matrix substrate includes a substrate, a plurality of gate signal lines, and a gate drive circuit. The gate drive circuit includes a shift register having a plurality of stages. The plurality of stages are constituted by a plurality of unit circuits each including a plurality of oxide semiconductor TFTs. The plurality of oxide semiconductor TFTs include at least one first TFT and at least one second TFT having lower mobility than does the first TFT. The at least one second TFT includes an oxide semiconductor TFT that becomes highest in drain-source electric field strength during operation of each unit circuit.

### CROSS-REFERENCE TO RELATED APPLICATIONS

This application claims the benefit of priority to Japanese Patent Application Number 2024-091803 filed on Jun. 5, 2024. The entire contents of the above-identified application are hereby incorporated by reference.

### BACKGROUND

### 1. Field

The present disclosure relates to active matrix substrate and, in particular, to an active matrix substrate including an oxide semiconductor TFT. Further, the present disclosure also relates to a display device including such an active matrix substrate.

### 2. Description of the Related Art

An active matrix substrate that is used in a liquid crystal display device, an organic electroluminescence (EL) display device, or other display devices has a display region having a plurality of pixels and a non-display region (sometimes also called “frame region”) located around the display region. In the display region, thin-film transistors (hereinafter referred to as “TFTs”) are provided separately for each of the pixels. Conventionally, as the TFTs provided separately for each of the pixels, TFTs each having an amorphous silicon film as an active layer (hereinafter referred to as “amorphous silicon TFTs) and TFTs each having a polycrystalline silicon film as an active layer (hereinafter referred to as “polycrystalline silicon TFTs”) have been widely used.

It is proposed to use an oxide semiconductor instead of amorphous silicon or polycrystalline silicon as a material of an active layer of a TFT. Such a TFT is referred to as an “oxide semiconductor TFT”. An oxide semiconductor has higher mobility than does amorphous silicon. Therefore, an oxide semiconductor TFT can operate at a higher speed than can an amorphous silicon TFT.

TFT structures are broadly divided into a bottom-gate structure and a top-gate structure. While the bottom-gate structure is currently often employed in organic semiconductor TFTs, it is also proposed to use the top-gate structure (see, for example, Japanese Unexamined Patent Application Publication No. 2013-21312). The top-gate structure, in which a gate insulating layer can be thinned, gives high current supply performance.

Further, in the non-display region of the active matrix substrate, peripheral circuits including TFTs may be monolithically (integrally) formed. Monolithically forming the peripheral circuits makes it possible to achieve narrowing of the non-display region (frame narrowing) and a reduction in cost by simplification of a mounting process. For example, in the non-display region, a gate driver circuit (gate drive circuit) may be monolithically formed, and a source driver circuit (source drive circuit) may be mounted by a COG (chip-on-glass) method. The gate driver circuit monolithically formed is called “GDM (gate driver monolithic) circuit”. International Publication No. 2011/055584 discloses a liquid crystal display device in which a GDM circuit is formed on top of an active matrix substrate.

The TFTs disposed separately for each of the pixels of the display region are herein called “pixel TFTs”. Further, the TFTs of the peripheral circuits provided in the non-display region are called “circuit TFTs”. In a case where the pixel TFTs are oxide semiconductor TFTs, it is preferable, from the point of view of a manufacturing process, that the circuit TFTs be also oxide semiconductor TFTs.

As a result of conducting various studies of active matrix substrates in which oxide semiconductor TFTs are used as circuit TFTs, the inventors found that a circuit TFT that is prone to characteristic degradation is present in a GDM circuit.

It is desirable to provide an active matrix substrate that makes it possible to reduce characteristic degradation of an oxide semiconductor TFT in a gate drive circuit.

### SUMMARY

According to an aspect of the disclosure, there is provided an active matrix substrate including a substrate, a plurality of gate signal lines supported by the substrate, and a gate drive circuit that drives the plurality of gate signal lines. The gate drive circuit includes a shift register having a plurality of stages associated with the plurality of gate signal lines. The plurality of stages are constituted by a plurality of unit circuits each including a plurality of oxide semiconductor TFTs. The plurality of oxide semiconductor TFTs include at least one first TFT each including a first oxide semiconductor layer and at least one second TFT each including a second oxide semiconductor layer and having lower mobility than does the at least one first TFT. The at least one second TFT includes, of the plurality of oxide semiconductor TFTs, an oxide semiconductor TFT that becomes highest in drain-source electric field strength during operation of each unit circuit.

According to an aspect of the disclosure, there is provided a display device including the aforementioned active matrix substrate.

### BRIEF DESCRIPTION OF THE DRAWINGS

FIG. 1 is a schematic cross-sectional view schematically showing a liquid crystal display device according to an embodiment of the present disclosure;

FIG. 2 is a schematic plan view schematically showing the liquid crystal display device;

FIG. 3 is an equivalent circuit diagram of one pixel of the liquid crystal display device;

FIG. 4 is a graph obtained by plotting combinations of a gate-source voltage Vgs and a drain-source field Eds during operation of a unit circuit of a certain configuration for eleven oxide semiconductor TFTs included in the unit circuit;

FIG. 5 is a cross-sectional view schematically showing an active matrix substrate of the liquid crystal display device with a first TFT shown on the right side and a second TFT shown on the left side;

FIG. 6A is a step cross-sectional view for explaining a method for manufacturing an active matrix substrate;

FIG. 6B is a step cross-sectional view for explaining the method for manufacturing an active matrix substrate;

FIG. 6C is a step cross-sectional view for explaining the method for manufacturing an active matrix substrate;

FIG. 6D is a step cross-sectional view for explaining the method for manufacturing an active matrix substrate;

FIG. 6E is a step cross-sectional view for explaining the method for manufacturing an active matrix substrate;

FIG. 6F is a step cross-sectional view for explaining the method for manufacturing an active matrix substrate;

FIG. 6G is a step cross-sectional view for explaining the method for manufacturing an active matrix substrate;

FIG. 6H is a step cross-sectional view for explaining the method for manufacturing an active matrix substrate;

FIG. 6I is a step cross-sectional view for explaining the method for manufacturing an active matrix substrate;

FIG. 6J is a step cross-sectional view for explaining the method for manufacturing an active matrix substrate;

FIG. 7 is a cross-sectional view schematically showing an active matrix substrate with a first TFT shown on the right side and a second TFT shown on the left side;

FIG. 8A is a step cross-sectional view for explaining a method for manufacturing an active matrix substrate;

FIG. 8B is a step cross-sectional view for explaining the method for manufacturing an active matrix substrate;

FIG. 8C is a step cross-sectional view for explaining the method for manufacturing an active matrix substrate;

FIG. 8D is a step cross-sectional view for explaining the method for manufacturing an active matrix substrate;

FIG. 8E is a step cross-sectional view for explaining the method for manufacturing an active matrix substrate;

FIG. 8F is a step cross-sectional view for explaining the method for manufacturing an active matrix substrate;

FIG. 8G is a step cross-sectional view for explaining the method for manufacturing an active matrix substrate;

FIG. 9 is a schematic plan view schematically showing a liquid crystal display device including a first gate driver and a second gate driver;

FIG. 10 is a diagram showing an overall configuration of the first gate driver and the second gate driver;

FIG. 11 is a schematic circuit diagram showing a configuration of the first gate driver;

FIG. 12 is a circuit diagram showing a basic configuration of a unit circuit including a bistable circuit; and

FIG. 13 is a circuit diagram showing a detailed example of a configuration of a unit circuit including a bistable circuit.

### DESCRIPTION OF THE EMBODIMENTS

An embodiment of the present disclosure is described below with reference to the drawings. While a liquid crystal display device is taken as an example of a display device according to the embodiment of the present disclosure, the display device according to the embodiment of the present disclosure is not limited to the liquid crystal display device. For example, the display device according to the embodiment of the present disclosure may be an organic EL display device. Further, thin-film transistors in the following description are n-type TFTs, and an electrical connection relationship in a case where the n-type TFTs are used is described. Note that electrical connections of sources and drains of p-type TFTs are opposite to electrical connections of sources and drains of the n-type TFTs.

### Schematic Configuration of Liquid Crystal Display Device

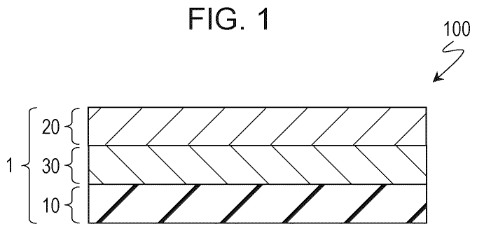

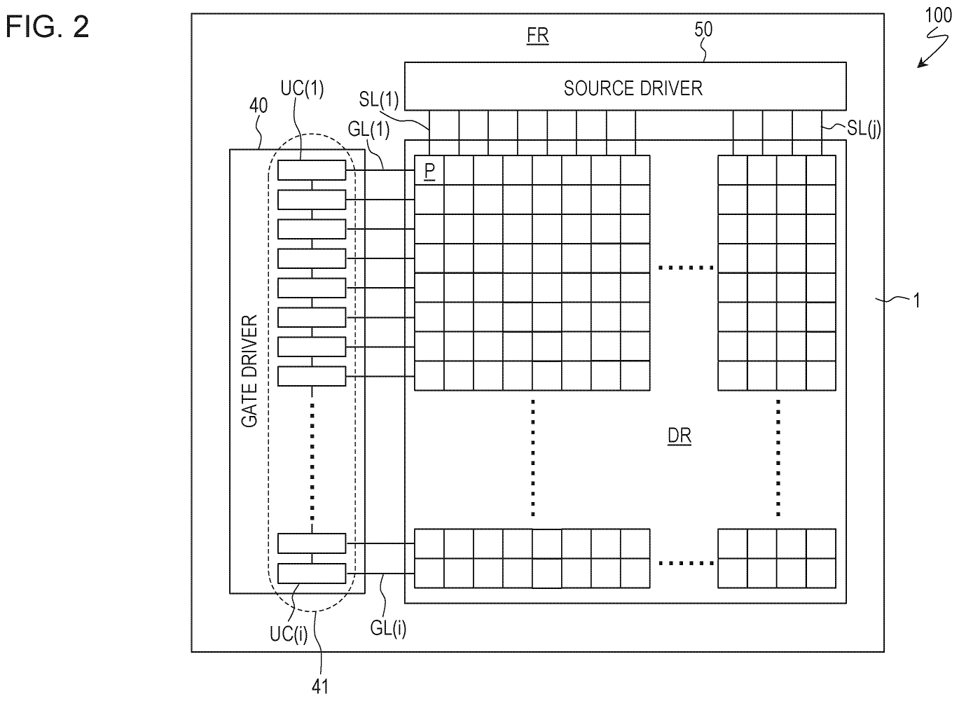

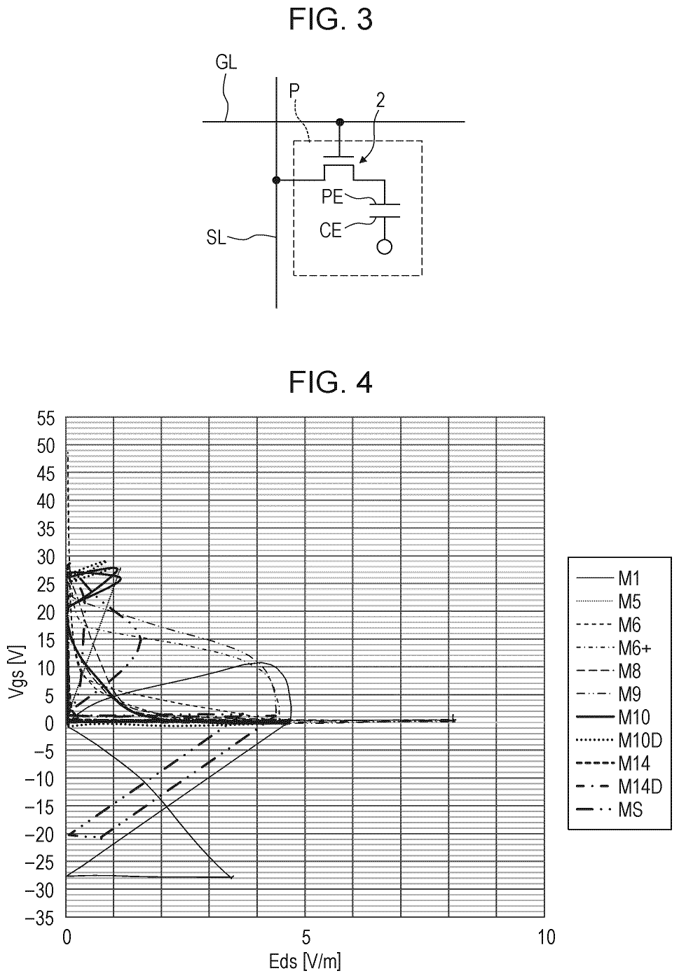

First, a schematic configuration of a liquid crystal display device 100 according to an embodiment of the present disclosure is described with reference to FIGS. 1, 2, and 3. FIGS. 1 and 2 are a schematic cross-sectional view and a schematic plan view schematically showing the liquid crystal display device 100, respectively. FIG. 3 is an equivalent circuit diagram of one pixel P of the liquid crystal display device 100.

As shown in FIG. 1, the liquid crystal display device 100 includes a display panel 1. The display panel 1 includes an active matrix substrate (hereinafter also called “TFT substrate”) 10, a counter substrate (also called “color filter substrate”) 20 placed opposite the active matrix substrate 10, and a liquid crystal layer 30 provided between the TFT substrate 10 and the counter substrate 20.

As shown in FIG. 2, the liquid crystal display device 100 has a display region DR and a non-display region (also called “peripheral region” or “frame region”) FR. The display region DR is defined by a plurality of pixels P. The plurality of pixels P are arrayed in a matrix including a plurality of rows and a plurality of columns. The non-display region FR is a region, located around the display region DR, that does not contribute to a display.

The display panel 1 (more specifically the TFT substrate 10) of the liquid crystal display device 100 has a plurality of (i) gate bus lines (gate signal lines) GL(1) to GL(i) and a plurality of (j) source bus lines (source signal lines) SL(1) to SL(j). Whereas the gate bus lines GL(1) to GL(i) (sometimes collectively denoted as “gate bus lines GL”) extend in a row-wise direction, the source bus lines SL(1) to SL(j) (sometimes collectively denoted as “source bus lines SL”) extend in a column-wise direction (substantially orthogonal to the row-wise direction). The gate bus lines GL and the source bus lines SL are supported by the after-mentioned substrate 10a.

As shown in FIG. 3, each pixel P is provided with a thin-film transistor (pixel TFT) 2 and a pixel electrode PE. The pixel TFT 2 is supplied with a scanning signal (gate signal) from a corresponding one of the gate bus lines GL and supplied with a video signal (source signal) from a corresponding one of the source bus lines SL. The pixel TFT 2 is an oxide semiconductor TFT having an oxide semiconductor layer as an active layer. The pixel electrode PE is electrically connected to the pixel TFT 2. A common electrode CE is placed opposite the pixel electrode PE.

The liquid crystal display device 100 further includes a gate driver (gate drive circuit) 40 that drives the gate bus lines GL(1) to GL(i) and a source driver (source drive circuit) 50 that drives the source bus lines SL(1) to SL(j). The gate driver 40 and the source driver 50 are placed in the non-display region FR.

The gate driver 40 brings the plurality of gate bus lines GL(1) to GL(i) into a selected state (i.e. a state of being supplied with a high-level potential of a scanning signal) in sequence. The gate driver 40 has a shift register 41 having a plurality of stages (in this example, i stages). The plurality of stages are associated with the plurality of gate bus lines GL (i.e. a plurality of pixel rows). The plurality of stages are constituted by a plurality of unit circuits UC. In the illustrated example, each stage is constituted by one unit circuit UC. That is, the shift register 41 has i unit circuits UC(1) to UC(i). In this example, the gate driver 40 is monolithically formed in the active matrix substrate 10. That is, the gate driver 40 is a GDM circuit. Although, typically, one unit circuit UC constitutes one stage, one unit circuit UC may constitute two stages as will be illustrated later.

### Configuration of Unit Circuit

Each unit circuit UC includes a plurality of oxide semiconductor TFTs as circuit TFTs. Each oxide semiconductor TFT includes an oxide semiconductor layer as an active layer.

The plurality of oxide semiconductor TFTs of the unit circuit UC include at least one first TFT and at least one second TFT having lower mobility than does the first TFT. That is, the unit circuit UC includes both a first TFT that is relatively high in mobility and a second TFT that is relatively low in mobility. The at least one second TFT includes, of the plurality of oxide semiconductor TFTs in the unit circuit UC, an oxide semiconductor TFT that becomes highest in strength of a drain-source electric field Eds during operation of the unit circuit UC.

According to the inventors' studies, it was found that a circuit TFT that is prone to characteristic degradation is present in a GDM circuit. According to their more detailed studies, it was found that a circuit TFT that becomes comparatively strong in drain-source electric field Eds during operation of a shift register is prone to characteristic degradation.

By configuring the embodiment of the present disclosure such that each unit circuit UC includes both a first TFT that is relatively high in mobility and a second TFT that is relatively low in mobility, that the second TFT is used as a circuit TFT that is comparatively strong in drain-source electric field Eds during operation of the unit circuit UC, and that the first TFT is used as a circuit that is comparatively weak in drain-source electric field Eds, the source-drain withstand voltage of the circuit TFT that is comparatively strong in drain-source electric field Eds can be increased while an increase in circuit size of the gate drive circuit (GDM circuit) 40 is suppressed. This makes it possible to reduce characteristic degradation of the oxide semiconductor TFTs in the gate drive circuit 40.

As illustrated, from the point of view of effectively reducing characteristic degradation, the at least one second TFT that is present in the unit circuit UC may include an oxide semiconductor TFT that becomes highest in strength of a drain-source electric field Eds during operation of the unit circuit UC. Moreover, in a case where the unit circuit UC includes a plurality of, i.e. n (where n is an integer greater than or equal to 2), second TFTs, the second TFTs may be oxide semiconductor TFTs that are first to nth highest in strength of a drain-source electric field Eds during operation of the unit circuit UC when the oxide semiconductor TFTs in the unit circuit UC are ranked according to the strength. In other words, the second TFTs may be preferentially oxide semiconductor TFTs that are high in strength of a drain-source electric field Eds.

FIG. 4 is a graph obtained by plotting combinations of a gate-source voltage Vgs and a drain-source field Eds during operation of a unit circuit UC of a certain configuration for eleven oxide semiconductor TFTs (denoted as “M1”, “M5”, “M6”, “M6+”, “M8”, “M9”, “M10”, “M10D”, “M14”, “M14D”, and “MS” in FIG. 4) included in the unit circuit UC.

In the example shown in FIG. 4, M8 and M9 are highest in strength of a drain-source field Eds during operation of the unit circuit UC, and M1 is second highest. Therefore, it can be said that in a case where the unit circuit UC includes two second TFTs, it is preferable that the second TFTs be M8 and M9, and it can be said that in a case where the unit circuit UC includes three second TFTs, it is preferable that the second TFTs be M1, M8, and M9.

### Specific Examples of First TFT and Second TFT

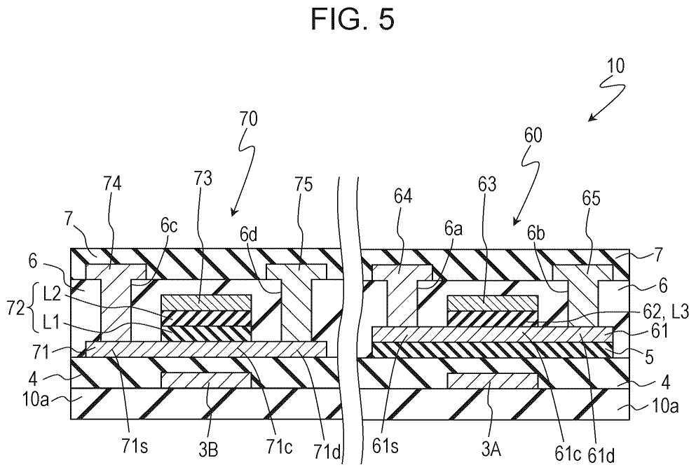

Specific examples of the aforementioned first and second TFTs are described with reference to FIG. 5. Although, in this example, a first TFT and a second TFT each having a top-gate structure are illustrated, the first TFT and the second TFT may each have a bottom-gate structure. FIG. 5 is a schematic cross-sectional view of the active matrix substrate 10 with a first TFT 60 shown on the right side of FIG. 5 and a second TFT 70 shown on the left side of FIG. 5.

As already mentioned, the active matrix substrate 10 has at least one first TFT 60 and at least one second TFT 70 in a region corresponding to each unit circuit UC. The first TFT 60 and the second TFT 70 are supported by the substrate 10a.

The first TFT 60 has a first oxide semiconductor layer 61, a first gate insulating layer 62, a first gate electrode 63, a first source electrode 64, and a first drain electrode 65.

The first oxide semiconductor layer 61 includes a first channel region 61c and includes a first source contact region 61s and a first drain contact region 61d that are located on both sides, respectively, of the first channel region 61c. The first source contact region 61s and the first drain contact region 61d can be low-resistance regions that are lower in specific resistance than the first channel region 61c. The low-resistance regions can be formed, for example, by performing a resistance-lowering process on the first oxide semiconductor layer 61 with the first gate electrode 63 as a mask.

The first gate insulating layer 62 is provided on top of at least the first channel region 61c of the first oxide semiconductor layer 61. The first gate electrode 63 is placed over the first channel region 61c of the first oxide semiconductor layer 61 with the first gate insulating layer 62 sandwiched between the first gate electrode 63 and the first channel region 61c. Although, in the example shown here, the first gate insulating layer 62 covers the first channel region 61c and does not cover the first source contact region 61s or the first drain contact region 61d, the first gate insulating layer 62 may cover the first source contact region 61s and/or the first drain contact region 61d.

The first source electrode 64 is electrically connected to the first source contact region 61s of the first oxide semiconductor layer 61. The first drain electrode 65 is electrically connected to the first drain contact region 61d of the first oxide semiconductor layer 61.

In the illustrated example, a first light-blocking layer 3A is provided at a side of the first oxide semiconductor layer 61 that faces the substrate 10a. The first light-blocking layer 3A is covered by a foundation insulating layer 4, and the first oxide semiconductor layer 61 is provided over the foundation insulating layer 4. In the illustrated example, a lower insulating layer 5 is sandwiched between the first oxide semiconductor layer 61 and the foundation insulating layer 4.

When seen from a direction normal to the substrate 10a, the first light-blocking layer 3A is disposed to overlap at least the first channel region 61c of the first oxide semiconductor layer 61. This makes it possible to reduce characteristic degradation of the first oxide semiconductor layer 61 attributed to light (backlight) from the substrate 10a. In a case where the first light-blocking layer 3A is formed from an electrically conducting material, the first light-blocking layer 3A may be electrically floating or may be fixed at a GND potential (0 V). Alternatively, the first light-blocking layer 3A may be electrically connected to the first gate electrode 63 to function as a lower gate electrode.

The second TFT 70 has a second oxide semiconductor layer 71, a second gate insulating layer 72, a second gate electrode 73, a second source electrode 74, and a second drain electrode 75.

The second oxide semiconductor layer 71 includes a second channel region 71c and includes a second source contact region 71s and a second drain contact region 71d that are located on both sides, respectively, of the second channel region 71c. The second source contact region 71s and the second drain contact region 71d can be low-resistance regions that are lower in specific resistance than the second channel region 71c. The low-resistance regions can be formed, for example, by performing a resistance-lowering process on the second oxide semiconductor layer 71 with the second gate electrode 73 as a mask.

The second gate insulating layer 72 is provided on top of at least the second channel region 71c of the second oxide semiconductor layer 71. The second gate electrode 73 is placed over the second channel region 71c of the second oxide semiconductor layer 71 with the second gate insulating layer 72 sandwiched between the second gate electrode 73 and the second channel region 71c. Although, in the example shown here, the second gate insulating layer 72 covers the second channel region 71c and does not cover the second source contact region 71s or the second drain contact region 71d, the second gate insulating layer 72 may cover the second source contact region 71s and/or the second drain contact region 71d.

The second source electrode 74 is electrically connected to the second source contact region 71s of the second oxide semiconductor layer 71. The second drain electrode 75 is electrically connected to the second drain contact region 71d of the second oxide semiconductor layer 71.

In the illustrated example, a second light-blocking layer 3B is provided at a side of the second oxide semiconductor layer 71 that faces the substrate 10a. The second light-blocking layer 3B is formed at a layer identical to that at which the first light-blocking layer 3A is formed, and is covered by the foundation insulating layer 4. The second oxide semiconductor layer 71 is provided on top of the foundation insulating layer 4.

When seen from a direction normal to the substrate 10a, the second light-blocking layer 3B is disposed to overlap at least the second channel region 71c of the second oxide semiconductor layer 71. This makes it possible to reduce characteristic degradation of the second oxide semiconductor layer 71 attributed to light (backlight) from the substrate 10a. In a case where the second light-blocking layer 3B is formed from an electrically conducting material, the second light-blocking layer 3B may be electrically floating or may be fixed at a GND potential (0 V). Alternatively, the second light-blocking layer 3B may be electrically connected to the second gate electrode 73 to function as a lower gate electrode.

In the illustrated example, the second oxide semiconductor layer 71 of the second TFT 70 is formed at a layer different from that at which the first oxide semiconductor layer 61 of the first TFT 60 is formed. More specifically, the second oxide semiconductor layer 71 is formed at a lower layer than is the first oxide semiconductor layer 61. The second oxide semiconductor layer 71 is lower in mobility than the first oxide semiconductor layer 61.

Further, the second gate insulating layer 72 of the second TFT 70 has a stack structure including a first insulating layer L1 and a second insulating layer L2 placed on top of the first insulating layer L1. On the other hand, the first gate insulating layer 62 of the first TFT 60 includes a third insulating layer L3 formed at a layer identical to that at which the second insulating layer L2 is formed, and does not include an insulating layer formed at a layer identical to that at which the first insulating layer L1 is formed. The lower insulating layer 5 placed between the first oxide semiconductor layer 61 and the substrate 10a (more specifically between the first oxide semiconductor layer 61 and the foundation insulating layer 4) is formed at a layer identical to that at which the first insulating layer L1 is formed.

An interlayer insulating layer 6 is provided so as to cover the first oxide semiconductor layer 61, first gate insulating layer 62, and first gate electrode 63 of the first TFT 60 and the second oxide semiconductor layer 71, second gate insulating layer 72, and second gate electrode 73 of the second TFT 70. The first source electrode 64 and first drain electrode 65 of the first TFT 60 and the second source electrode 74 and second drain electrode 75 of the second TFT 70 are formed at an identical layer and placed on top of the interlayer insulating layer 6.

The interlayer insulating layer 6 has formed therein a first opening 6a and a second opening 6b through which the first source contact region 61s and first drain contact region 61d of the first oxide semiconductor layer 61 are exposed and a third opening 6c and a fourth opening 6d through which the second source contact region 71s and second drain contact region 71d of the second oxide semiconductor layer 71 are exposed. The first source electrode 64 is connected to the first source contact region 61s in the first opening 6a, and the first drain electrode 65 is connected to the first drain contact region 61d in the second opening 6b. Further, the second source electrode 74 is connected to the second source contact region 71s in the third opening 6c, and the second drain electrode 75 is connected to the second drain contact region 71d in the fourth opening 6d. An inorganic insulating layer 7 is provided so as to cover the first source electrode 64, the first drain electrode 65, the second source electrode 74, and the second drain electrode 75.

Employing the structure illustrated in FIG. 5 makes it possible to easily separately fabricate, over the identical substrate 10a, a first TFT 60 that is relatively high in mobility and a second TFT 70 that is relatively low in mobility.

The first oxide semiconductor layer 61 and the second oxide semiconductor layer 71 are not limited to particular compositions, crystal structures, thicknesses, methods of formation, or other features.

The first oxide semiconductor layer 61 and the second oxide semiconductor layer 71 may be different in composition from each other. The phrase “different in composition” here means that the types or composition ratios of metallic elements contained in one layer are different from the types or composition ratios of metallic elements contained in the other layer. For example, the first oxide semiconductor layer 61 and the second oxide semiconductor layer 71 may each contain In and/or Sn, and the sum of the ratios of the numbers of atoms of In and Sn to those of all metallic elements in the second oxide semiconductor layer 71 may be smaller than the sum of the ratios of the numbers of atoms of In and Sn to those of all metallic elements in the first oxide semiconductor layer 61.

Alternatively, the first oxide semiconductor layer 61 and the second oxide semiconductor layer 71 may both be In—Ga—Zn—O oxide semiconductor layers, and the ratio of the number of atoms of In in the second oxide semiconductor layer 71 may be lower than the ratio of the number of atoms of In in the first oxide semiconductor layer 61. In this case, in either the first oxide semiconductor layer 61 or the second oxide semiconductor layer 71, the ratio of the number of atoms of In to those of all metallic elements and the ratio of the number of atoms of Zn to those of all metallic elements may be equal to each other.

Further, the first oxide semiconductor layer 61 may contain Sn, and the second oxide semiconductor layer 71 may not contain Sn. Alternatively, the second oxide semiconductor layer 71 may contain Sn in lower concentration than does the first oxide semiconductor layer 61. That is, the ratio of the number of atoms of Sn to those of all metallic elements in the second oxide semiconductor layer 71 may be lower than the ratio of the number of atoms of Sn to those of all metallic elements in the first oxide semiconductor layer 61.

A usable example of the second oxide semiconductor layer 71 is an In—Ga—Zn—O semiconductor layer (such as In:Ga:Zn=1:1:1). Usable examples of the first oxide semiconductor layer 61 include an In—Ga—Zn—O semiconductor layer (such as In:Ga:Zn=3:1:2), an In—Sn—Zn—O semiconductor layer, an In—Al—Sn—Zn—O semiconductor layer, an In—W—Zn—O semiconductor layer, an In—Sn—O semiconductor layer, an In—Zn—O semiconductor layer, an In—Ga—Sn—O semiconductor layer, and an In—Sn—Ti—Zn—O semiconductor layer.

Further, the first oxide semiconductor layer 61 and the second oxide semiconductor layer 71 may have crystal structures that are different from each other. For example, one of the first oxide semiconductor layer 61 and the second oxide semiconductor layer 71 may be an amorphous oxide semiconductor layer, and the other of the first oxide semiconductor layer 61 and the second oxide semiconductor layer 71 may be a crystalline oxide semiconductor layer including a crystalline portion.

Even in a case where the ratios of metallic elements of the first oxide semiconductor layer 61 and the second oxide semiconductor layer 71 are equal to each other, varying methods of film formation or conditions for film formation makes it possible to make these oxide semiconductor layers different in mobility from each other. For example, in forming oxide semiconductor layers of the same ratios of metallic elements by sputtering as the first oxide semiconductor layer 61 and the second oxide semiconductor layer 71, atmospheres in a chamber (e.g. flow ratios between oxygen and Ar that are supplied to the chamber) may be varied. Specifically, when the second oxide semiconductor layer 71 is formed, the flow ratio of oxygen to Ar may be set high (e.g. 80%), and when the first oxide semiconductor layer 61 is formed, the flow ratio of oxygen to Ar may be set lower (e.g. 20%) than when the second oxide semiconductor layer 71 is formed. This makes it possible to make the second oxide semiconductor layer 71 lower in mobility than the first oxide semiconductor layer 61.

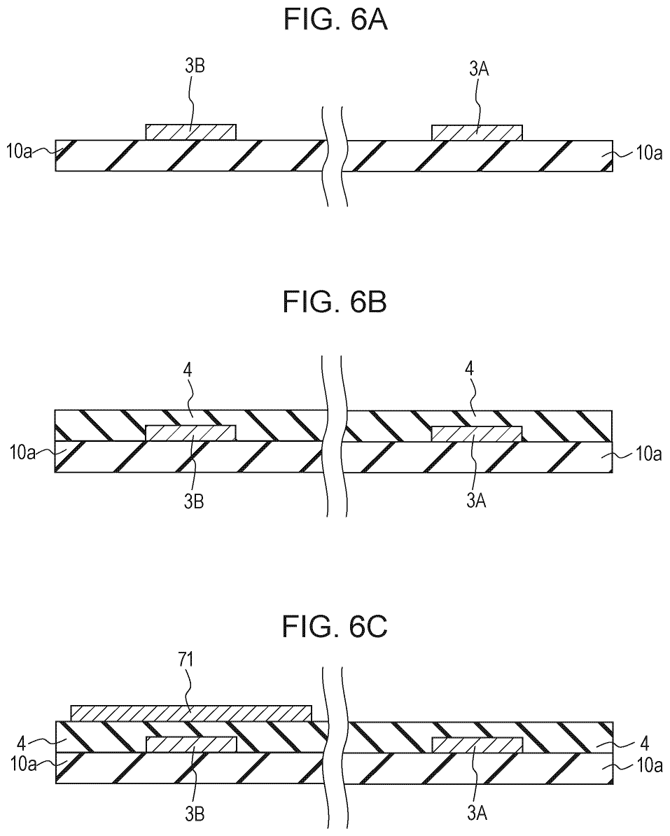

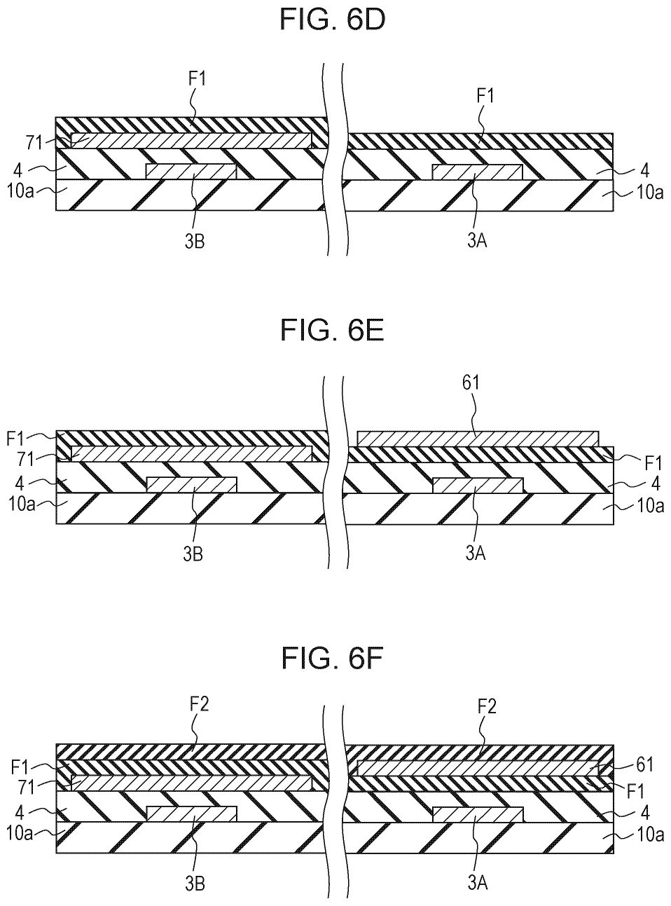

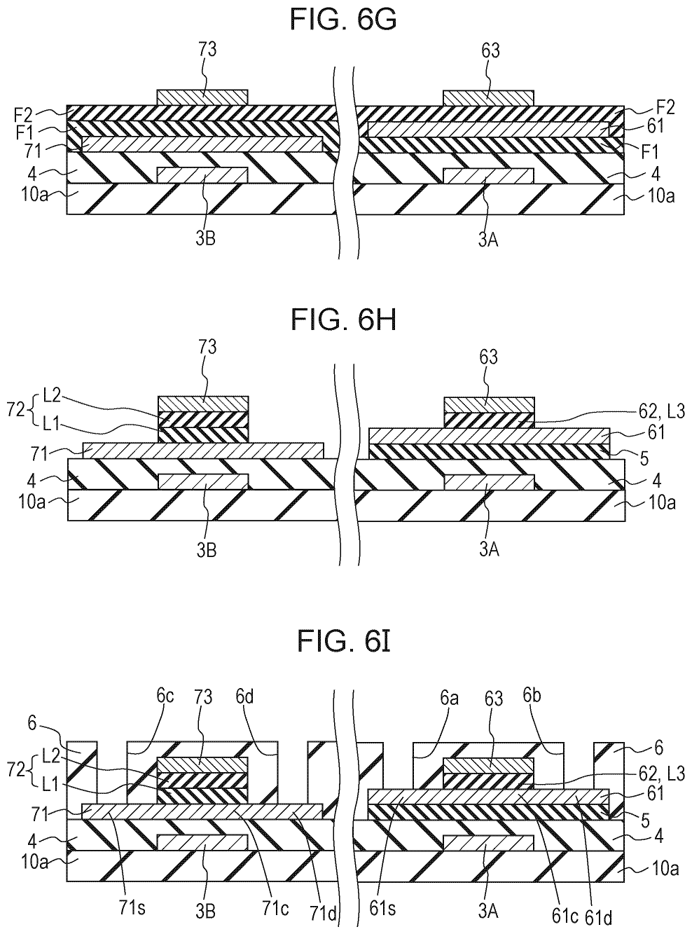

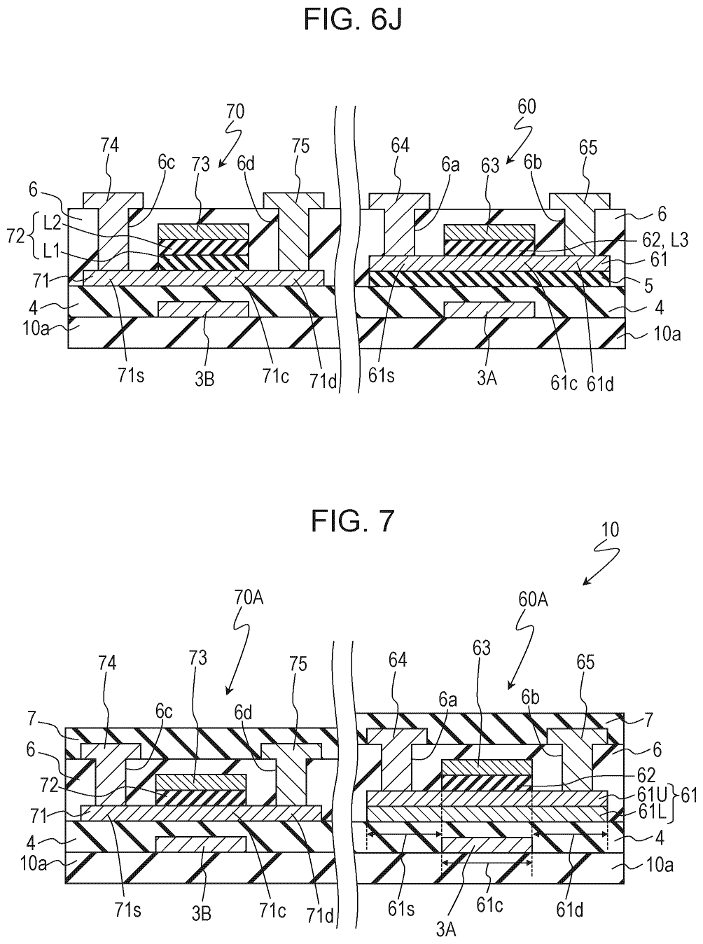

A method for manufacturing an active matrix substrate 10 having a first TFT 60 and a second TFT 70 as illustrated in FIG. 5 is described below with reference to FIGS. 6A to 6J. FIGS. 6A to 6J are step cross-sectional views for explaining a method for manufacturing an active matrix substrate 10.

First, as shown in FIG. 6A, the first light-blocking layer 3A and the second light-blocking layer 3B are formed on top of the substrate 10a. Specifically, the first light-blocking layer 3A and the second light-blocking layer 3B can be formed by forming a light-blocking conducting film (whose thickness is, for example, greater than or equal to 50 nm and less than or equal to 500 nm) by sputtering or other processes on an insulating substrate 10a and then patterning the light-blocking conducting film.

Usable examples of the substrate 10a include a glass substrate and a plastic substrate (resin substrate) having heat resistance.

Usable examples of the light-blocking conducting film include a metal film containing an element selected from among aluminum (Al), chromium (Cr), copper (Cu), tantalum (Ta), titanium (Ti), molybdenum (Mo), and tungsten (W) and an alloy film composed of these elements. Further, a laminated film including a plurality of films of these may be used. In this example, a metal film or an alloy film containing Cu or Al is used as the light-blocking conducting film.

Next, as shown in FIG. 6B, the foundation insulating layer 4 is formed so as to cover the first light-blocking layer 3A and the second light-blocking layer 3B. The foundation insulating layer 4 can be formed, for example, by CVD. The foundation insulating layer 4 has a thickness greater than or equal to 200 nm and less than or equal to 600 nm.

Appropriately usable examples of the foundation insulating layer 4 include a silicon oxide (SiO₂) layer, a silicon nitride (SiNx) layer, a silicon oxynitride (SiOxNy; x>y), and a silicon nitroxide (SiNxOy; x>y). The foundation insulating layer 4 may have a stack structure. For example, on the substrate 10a (lower layer), a silicon nitride layer, a silicon nitroxide layer, or other layers may be formed for the avoidance of diffusion of impurities from the substrate 10a, and at a layer (upper layer) higher than the layer thus formed, a silicon oxide layer, a silicon oxynitride layer, or other layers may be formed for the securement of insulation properties.

Then, as shown in FIG. 6C, the second oxide semiconductor layer 71 is formed on top of the foundation insulating layer 4. Specifically, the second oxide semiconductor layer 71 can be formed by depositing an oxide semiconductor film by sputtering first and then patterning the oxide semiconductor film. In this example, an In—Ga—Zn—O semiconductor film (In:Ga:Zn=1:1:1) is used as the oxide semiconductor film for the second oxide semiconductor layer 71. The oxide semiconductor film can be patterned, for example, by wet etching involving the use of a PAN etchant containing phosphoric acid, nitric acid, and acetic acid or an oxalic acid etchant.

Next, as shown in FIG. 6D, an insulating film (hereinafter called “first insulating film”) F1 is deposited so as to cover the foundation insulating layer 4 and the second oxide semiconductor layer 71. The first insulating film F1 can be deposited, for example, by CVD. In this example, a silicon oxide film is used as the first insulating film F1.

Then, as shown in FIG. 6E, the first oxide semiconductor layer 61 is formed on top of the first insulating film F1. Specifically, the first oxide semiconductor layer 61 can be formed by depositing an oxide semiconductor film by sputtering first and then patterning the oxide semiconductor film. In this example, an In—Ga—Zn—O semiconductor film is used as the oxide semiconductor film for the first oxide semiconductor layer 61. As can be seen from the foregoing description, the first oxide semiconductor layer 61 can be made lower in mobility than the second oxide semiconductor layer 71, for example, by making the ratio of the number of atoms of In in the first oxide semiconductor layer 61 higher than the ratio of the number of atoms of In in the second oxide semiconductor layer 71.

Next, as shown in FIG. 6F, an insulating film (hereinafter called “second insulating film”) F2 is deposited so as to cover the first insulating film F1 and the first oxide semiconductor layer 61. The second insulating film F2 can be deposited, for example, by CVD. In this example, a silicon oxide film is used as the second insulating film F2.

Then, as shown in FIG. 6G, the first gate electrode 63 and the second gate electrode 73 are formed on top of the second insulating film F2. Specifically, the first gate electrode 63 and the second gate electrode 73 can be formed by forming a gate conducting film (whose thickness is, for example, greater than or equal to 50 nm and less than or equal to 500 nm) by sputtering or other processes and then patterning the gate conducting film. As the gate conducting film, a conducting film similar to the light-blocking conducting film can be used.

Next, as shown in FIG. 6H, the first insulating film F1 and the second insulating film F2 are patterned. Specifically, the first insulating film F1 and the second insulating film F2 are patterned by using, as masks, a resist mask (not illustrated) used in the patterning of the gate conducting film and the first oxide semiconductor layer 61. Instead of the resist mask, the first gate electrode 63 and the second gate electrode 73 may be used as masks.

A portion of the second insulating film F2 that remains between the first gate electrode 63 and the first oxide semiconductor layer 61 serves as the first gate insulating layer 62. The first gate insulating layer 62 has a single-layer structure including the third insulating layer L3 formed from the second insulating film F2. Further, a portion of the first insulating film F1 and the second insulating film F2 that remains between the second gate electrode 73 and the second oxide semiconductor layer 71 serves as the second gate insulating layer 72. The second gate insulating layer 72 has a stack structure including the first insulating layer L1 formed from the first insulating film F1 and the second insulating layer L2 formed from the second insulating film F2. Furthermore, a portion of the first insulating film F1 that remains between the first oxide semiconductor layer 61 and the foundation insulating layer 4 serves as the lower insulating layer 5.

After this, a resistance-lowering process may be performed on the first oxide semiconductor layer 61 and the second oxide semiconductor layer 71. The resistance-lowering process is, for example, a plasma process. The resistance-lowering process causes regions of the first oxide semiconductor layer 61 that do not overlap the first gate electrode 63 to be low-resistance regions (i.e. the first source contact region 61s and the first drain contact region 61d) that are lower in specific resistance than a region (i.e. the channel region 61c) of the first oxide semiconductor layer 61 that overlaps the first gate electrode 63. Similarly, the resistance-lowering process causes regions of the second oxide semiconductor layer 71 that do not overlap the second gate electrode 73 to be low-resistance regions (i.e. the second source contact region 71s and the second drain contact region 71d) that are lower in specific resistance than a region (i.e. the channel region 71c) of the second oxide semiconductor layer 71 that overlaps the second gate electrode 73. The resistance-lowering process is not limited to the method illustrated here.

Next, as shown in FIG. 6I, the interlayer insulating layer 6 is formed so as to cover the first oxides semiconductor layer 61, the second oxide semiconductor layer 71, the first gate insulating layer 62, the second gate insulating layer 72, the first gate electrode 63, and the second gate electrode 73. The interlayer insulating layer 6 can be formed, for example, by CVD. Usable examples of the interlayer insulating layer 6 include a silicon oxide layer, a silicon nitride layer, a silicon oxynitride layer, and a silicon nitroxide layer. Using, as the interlayer insulating layer 6, an insulating layer that reduces an oxide semiconductor layer such as a silicon nitride layer makes it possible to keep low the specific resistance of regions of the first oxides semiconductor layer 61 and the second oxide semiconductor layer 71 that make contact with the interlayer insulating layer 6.

After that, the first opening 6a, the second opening 6b, the third opening 6c, and the fourth opening 6d are formed in the interlayer insulating layer 6. Specifically, the first opening 6a, the second opening 6b, the third opening 6c, and the fourth opening 6d can be formed by a photolithography process and etching. The etching can be, for example, dry etching.

Next, as shown in FIG. 6J, the first source electrode 64 is formed on top of the interlayer insulating layer 6 and inside the first opening 6a, and the first drain electrode 65 is formed on top of the interlayer insulating layer 6 and inside the second opening 6b. Further, at this point in time, the second source electrode 74 is formed on top of the interlayer insulating layer 6 and inside the third opening 6c, and the second drain electrode 75 is formed on top of the interlayer insulating layer 6 and inside the fourth opening 6d. Specifically, the first source electrode 63, the first drain electrode 64, the second source electrode 73, and the second drain electrode 74 can be formed by forming a source conducting film (whose thickness is, for example, greater than or equal to 50 nm and less than or equal to 500 nm) on top of the interlayer insulating layer 6, inside the first opening 6a, inside the second opening 6b, inside the third opening 6c, and inside the fourth opening 6d and then patterning the source conducting film. The source conducting film can be patterned, for example, by dry etching or wet etching. The source conducting film can be made, for example, of an element selected from among aluminum (Al), chromium (Cr), copper (Cu), tantalum (Ta), titanium (Ti), molybdenum (Mo), and tungsten (W), an alloy composed of these elements, or other materials. For example, the source conducting film may have a three-layer structure composed of a titanium film, an aluminum film, and a titanium film, a three-layer structure composed of a molybdenum film, an aluminum film, and a molybdenum film, or other three-layer structures. The source conducting film is not limited to a three-layer structure but may have a single-layer structure, a two-layer structure, or a stack structure composed of four or more layers. In this example, a laminated film composed of a Ti film (whose thickness is greater than or equal to 15 nm and less than or equal to 70 nm) as a lower layer and a Cu film (whose thickness is greater than or equal to 200 nm and less than or equal to 400 nm) as an upper layer is used.

After that, the inorganic insulating layer 7 (whose thickness is greater than or equal to 100 nm and less than or equal to 500 nm) is formed so as to cover the interlayer insulating layer 6, the first source electrode 63, the first drain electrode 64, the second source electrode 73, and the second drain electrode 74, whereby the active matrix substrate 10 illustrated in FIG. 5 is obtained. The inorganic insulating layer 7 can be formed, for example, by CVD. A usable example of the inorganic insulating layer 7 is an insulating layer illustrated as a specific example of the interlayer insulating layer 6. In this example, a silicon nitride layer is used as the inorganic insulating layer 7.

### Other Specific Examples of First TFT and Second TFT

Other specific examples of the first and second TFTs are described with reference to FIG. 7. Also in this example, a first TFT and a second TFT each having a top-gate structure are illustrated. FIG. 7 is a schematic cross-sectional view of the active matrix substrate 10 with a first TFT 60A shown on the right side of FIG. 7 and a second TFT 70A shown on the left side of FIG. 7. The following description focuses on points of difference between the first and second TFTs 60A and 70A and the first and second TFTs 60 and 70 shown in FIG. 5.

The first TFT 60A has a first oxide semiconductor layer 61, a first gate insulating layer 62, a first gate electrode 63, a first source electrode 64, and a first drain electrode 65. The first oxide semiconductor layer 61 of the first TFT 60A has a stack structure including a lower oxide semiconductor layer 61L and an upper oxide semiconductor layer 61U placed on top of the lower oxide semiconductor layer 61L. The upper oxide semiconductor layer 61U has lower mobility than does the lower oxide semiconductor layer 61L.

The second TFT 70A has a second oxide semiconductor layer 71, a second gate insulating layer 72, a second gate electrode 73, a second source electrode 74, and a second drain electrode 75. The second oxide semiconductor layer 71 of the second TFT 70A is formed at a layer identical to that at which the upper oxide semiconductor layer 61U of the first oxide semiconductor layer 61 is formed.

The first gate insulating layer 62 of the first TFT 60A and the second gate insulating layer 72 of the second TFT 70A are formed at an identical layer.

Employing the structure illustrated in FIG. 7 makes it possible to easily separately fabricate, over the identical substrate 10a, a first TFT 60A that is relatively high in mobility and a second TFT 70A that is relatively low in mobility.

The lower oxide semiconductor layer 61L and the upper oxide semiconductor layer 61U may be different in composition from each other. For example, the lower oxide semiconductor layer 61L and the upper oxide semiconductor layer 61U may each contain In and/or Sn, and the sum of the ratios of the numbers of atoms of In and Sn to those of all metallic elements in the upper oxide semiconductor layer 61U may be smaller than the sum of the ratios of the numbers of atoms of In and Sn to those of all metallic elements in the lower oxide semiconductor layer 61L.

Alternatively, the lower oxide semiconductor layer 61L and the upper oxide semiconductor layer 61U may both be In—Ga—Zn—O oxide semiconductor layers, and the ratio of the number of atoms of In in the upper oxide semiconductor layer 61U may be lower than the ratio of the number of atoms of In in the lower oxide semiconductor layer 61L. In this case, in either the first oxide semiconductor layer 61 or the second oxide semiconductor layer 71, the ratio of the number of atoms of In to those of all metallic elements and the ratio of the number of atoms of Zn to those of all metallic elements may be equal to each other.

Further, the lower oxide semiconductor layer 61L may contain Sn, and the upper oxide semiconductor layer 61U may not contain Sn. Alternatively, the upper oxide semiconductor layer 61U may contain Sn in lower concentration than does the lower oxide semiconductor layer 61L. That is, the ratio of the number of atoms of Sn to those of all metallic elements in the upper oxide semiconductor layer 61U may be lower than the ratio of the number of atoms of Sn to those of all metallic elements in the lower oxide semiconductor layer 61L.

A usable example of the upper oxide semiconductor layer 61U is an In—Ga—Zn—O semiconductor layer (such as In:Ga:Zn=1:1:1). Usable examples of the lower oxide semiconductor layer 61L include an In—Ga—Zn—O semiconductor layer (such as In:Ga:Zn=3:1:2), an In—Sn—Zn—O semiconductor layer, an In—Al—Sn—Zn—O semiconductor layer, an In—W—Zn—O semiconductor layer, an In—Sn—O semiconductor layer, an In—Zn—O semiconductor layer, an In—Ga—Sn—O semiconductor layer, and an In—Sn—Ti—Zn—O semiconductor layer.

Further, the lower oxide semiconductor layer 61L and the upper oxide semiconductor layer 61U may have crystal structures that are different from each other. For example, one of the lower oxide semiconductor layer 61L and the upper oxide semiconductor layer 61U may be an amorphous oxide semiconductor layer, and the other of the lower oxide semiconductor layer 61L and the upper oxide semiconductor layer 61U may be a crystalline oxide semiconductor layer including a crystalline portion.

Even in a case where the ratios of metallic elements of the lower oxide semiconductor layer 61L and the upper oxide semiconductor layer 61U are equal to each other, varying methods of film formation or conditions for film formation makes it possible to make these oxide semiconductor layers different in mobility from each other. For example, in forming oxide semiconductor layers of the same ratios of metallic elements by sputtering as the lower oxide semiconductor layer 61L and the upper oxide semiconductor layer 61U, atmospheres in a chamber (e.g. flow ratios between oxygen and Ar that are supplied to the chamber) may be varied. Specifically, when the upper oxide semiconductor layer 61U is formed, the flow ratio of oxygen to Ar may be set high (e.g. 80%), and when the lower oxide semiconductor layer 61L is formed, the flow ratio of oxygen to Ar may be set lower (e.g. 20%) than when the upper oxide semiconductor layer 61U is formed. This makes it possible to make the upper oxide semiconductor layer 61U lower in mobility than the lower oxide semiconductor layer 61L.

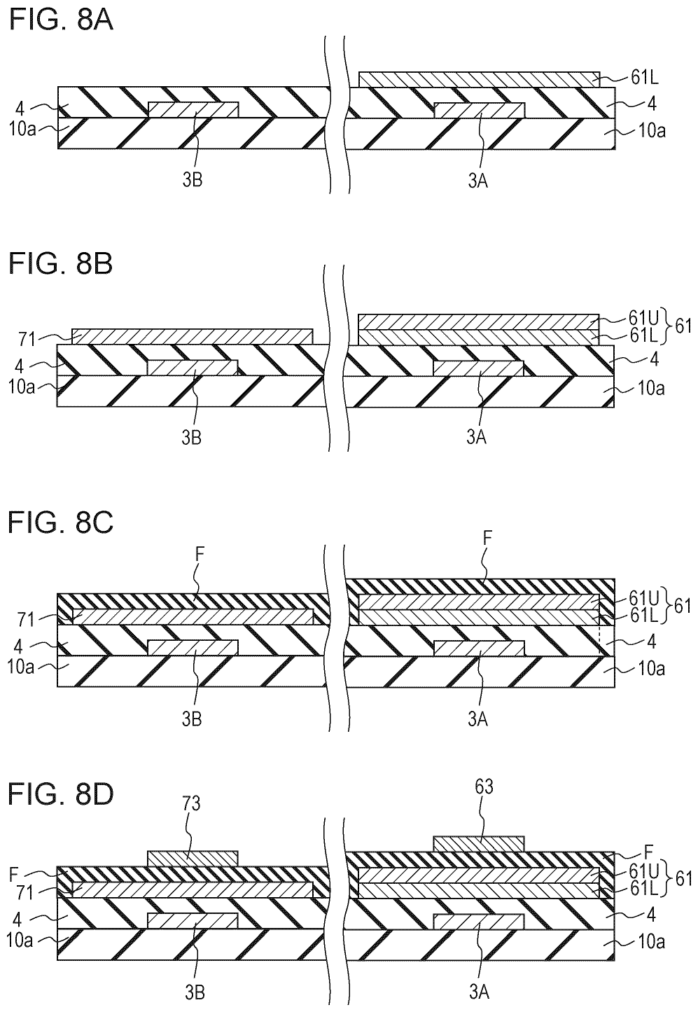

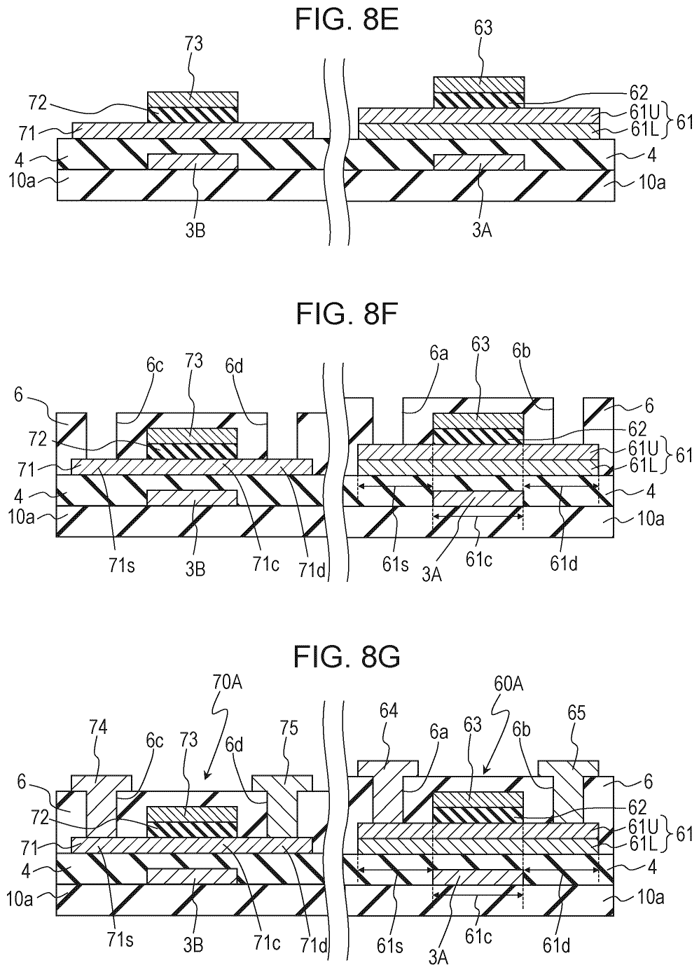

A method for manufacturing an active matrix substrate 10 having a first TFT 60A and a second TFT 70A as illustrated in FIG. 7 is described below with reference to FIGS. 8A to 8G. FIGS. 8A to 8G are step cross-sectional views for explaining a method for manufacturing an active matrix substrate 10.

First, the first light-blocking layer 3A, the second light-blocking layer 3B, and the foundation insulating layer 4 are formed on top of the substrate 10a in a manner similar to that described with reference to FIGS. 6A and 6B.

Next, as shown in FIG. 8A, the lower oxide semiconductor layer 61L is formed on top of the foundation insulating layer 4. Specifically, the lower oxide semiconductor layer 61L can be formed by depositing an oxide semiconductor film by sputtering first and then patterning the oxide semiconductor film. In this example, an In—Ga—Zn—O semiconductor film (In:Ga:Zn=5:1:4) having a thickness of 10 nm is used as the oxide semiconductor film for the lower oxide semiconductor layer 61L. Alternatively, a Sn-containing film such as an In—Sn—Zn—O semiconductor film (e.g. In₂O₃—SnO₂—ZnO) having a thickness of 10 nm may be used.

Then, as shown in FIG. 8B, the upper oxide semiconductor layer 61U is formed on top of the lower oxide semiconductor layer 61L, and the second oxide semiconductor layer 71 is formed on top of the foundation insulating layer 4. Specifically, the upper oxide semiconductor layer 61U and the second oxide semiconductor layer 71 can be formed by depositing an oxide semiconductor film by sputtering first and then patterning the oxide semiconductor film. In this example, an In—Ga—Zn—O semiconductor film (In:Ga:Zn=1:1:1) having a thickness of 40 nm is used as the oxide semiconductor film for the upper oxide semiconductor layer 61U and the second oxide semiconductor layer 71.

Next, as shown in FIG. 8C, an insulating film F is formed so as to cover the foundation insulating layer 4, the first oxide semiconductor layer 61, and the second oxide semiconductor layer 71. The insulating film F can be deposited, for example, by CVD. In this example, a silicon oxide film is used as the insulating film F.

Then, as shown in FIG. 8D, the first gate electrode 63 and the second gate electrode 73 are formed on top of the insulating film F. Specifically, the first gate electrode 63 and the second gate electrode 73 can be formed by forming a gate conducting film (whose thickness is, for example, greater than or equal to 50 nm and less than or equal to 500 nm) by sputtering or other processes and then patterning the gate conducting film. As the gate conducting film, a conducting film similar to the light-blocking conducting film can be used.

Next, as shown in FIG. 8E, the insulating film F is patterned. Specifically, the insulating film F is patterned by using, as a mask, a resist mask (not illustrated) used in the patterning of the gate conducting film. Instead of the resist mask, the first gate electrode 63 and the second gate electrode 73 may be used as masks. A portion of the insulating film F that remains between the first gate electrode 63 and the first oxide semiconductor layer 61 serves as the first gate insulating layer 62, and a portion of the insulating film F that remains between the second gate electrode 73 and the second oxide semiconductor layer 71 serves as the second gate insulating layer 72.

After this, a resistance-lowering process may be performed on the first oxide semiconductor layer 61 and the second oxide semiconductor layer 71. The resistance-lowering process is, for example, a plasma process. The resistance-lowering process causes regions of the first oxide semiconductor layer 61 that do not overlap the first gate electrode 63 to be low-resistance regions (i.e. the first source contact region 61s and the first drain contact region 61d) that are lower in specific resistance than a region (i.e. the channel region 61c) of the first oxide semiconductor layer 61 that overlaps the first gate electrode 63. Similarly, the resistance-lowering process causes regions of the second oxide semiconductor layer 71 that do not overlap the second gate electrode 73 to be low-resistance regions (i.e. the second source contact region 71s and the second drain contact region 71d) that are lower in specific resistance than a region (i.e. the channel region 71c) of the second oxide semiconductor layer 71 that overlaps the second gate electrode 73. The resistance-lowering process is not limited to the method illustrated here.

Next, as shown in FIG. 8F, the interlayer insulating layer 6 is formed so as to cover the first oxides semiconductor layer 61, the second oxide semiconductor layer 71, the first gate insulating layer 62, the second gate insulating layer 72, the first gate electrode 63, and the second gate electrode 73. The interlayer insulating layer 6 can be formed, for example, by CVD. Usable examples of the interlayer insulating layer 6 include a silicon oxide layer, a silicon nitride layer, a silicon oxynitride layer, and a silicon nitroxide layer. Using, as the interlayer insulating layer 6, an insulating layer that reduces an oxide semiconductor layer such as a silicon nitride layer makes it possible to keep low the specific resistance of regions of the first oxides semiconductor layer 61 and the second oxide semiconductor layer 71 that make contact with the interlayer insulating layer 6.

After that, the first opening 6a, the second opening 6b, the third opening 6c, and the fourth opening 6d are formed in the interlayer insulating layer 6. Specifically, the first opening 6a, the second opening 6b, the third opening 6c, and the fourth opening 6d can be formed by a photolithography process and etching. The etching can be, for example, dry etching.

Next, as shown in FIG. 8G, the first source electrode 64 is formed on top of the interlayer insulating layer 6 and inside the first opening 6a, and the first drain electrode 65 is formed on top of the interlayer insulating layer 6 and inside the second opening 6b. Further, at this point in time, the second source electrode 74 is formed on top of the interlayer insulating layer 6 and inside the third opening 6c, and the second drain electrode 75 is formed on top of the interlayer insulating layer 6 and inside the fourth opening 6d. Specifically, the first source electrode 63, the first drain electrode 64, the second source electrode 73, and the second drain electrode 74 can be formed by forming a source conducting film (whose thickness is, for example, greater than or equal to 50 nm and less than or equal to 500 nm) on top of the interlayer insulating layer 6, inside the first opening 6a, inside the second opening 6b, inside the third opening 6c, and inside the fourth opening 6d and then patterning the source conducting film. The source conducting film can be patterned, for example, by dry etching or wet etching. The source conducting film can be made, for example, of an element selected from among aluminum (Al), chromium (Cr), copper (Cu), tantalum (Ta), titanium (Ti), molybdenum (Mo), and tungsten (W), an alloy composed of these elements, or other materials. For example, the source conducting film may have a three-layer structure composed of a titanium film, an aluminum film, and a titanium film, a three-layer structure composed of a molybdenum film, an aluminum film, and a molybdenum film, or other three-layer structures. The source conducting film is not limited to a three-layer structure but may have a single-layer structure, a two-layer structure, or a stack structure composed of four or more layers. In this example, a laminated film composed of a Ti film (whose thickness is greater than or equal to 15 nm and less than or equal to 70 nm) as a lower layer and a Cu film (whose thickness is greater than or equal to 200 nm and less than or equal to 400 nm) as an upper layer is used.

After that, the inorganic insulating layer 7 (whose thickness is greater than or equal to 100 nm and less than or equal to 500 nm) is formed so as to cover the interlayer insulating layer 6, the first source electrode 63, the first drain electrode 64, the second source electrode 73, and the second drain electrode 74, whereby the active matrix substrate 10 illustrated in FIG. 7 is obtained. The inorganic insulating layer 7 can be formed, for example, by CVD. A usable example of the inorganic insulating layer 7 is an insulating layer illustrated as a specific example of the interlayer insulating layer 6. In this example, a silicon nitride layer is used as the inorganic insulating layer 7.

### Configuration of Gate Driver

A specific example of a configuration of gate drivers is described. While the gate drivers can be variously configured as has been publicly known, the gate drivers are described by taking, as an example, a configuration disclosed in U.S. Patent Application Publication No. 2020/0135132.

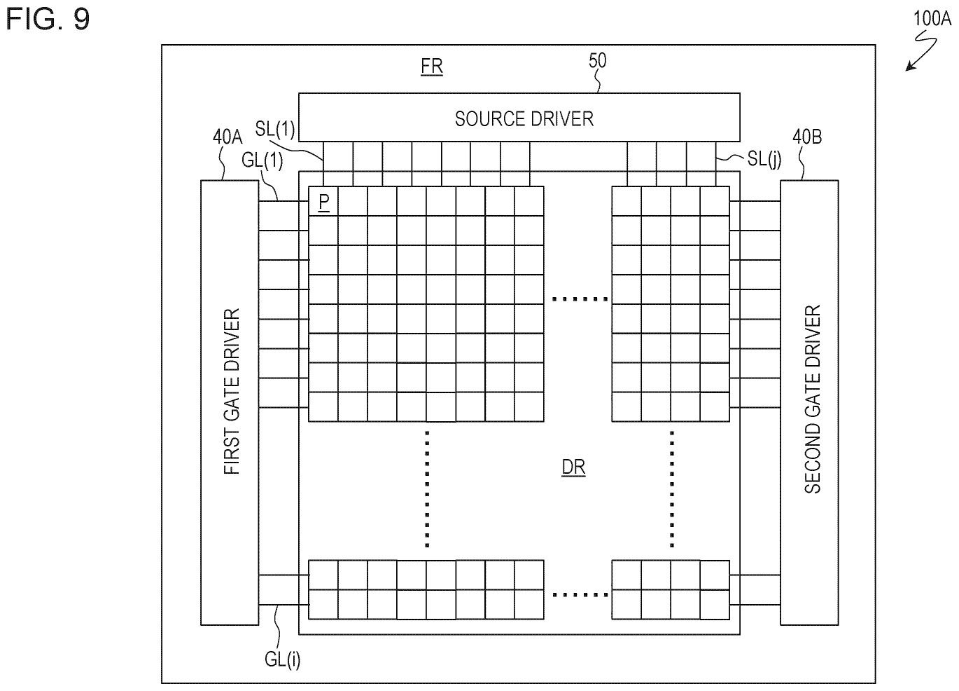

FIG. 9 is a schematic plan view schematically showing a liquid crystal display device 100A including a first gate driver 40A and a second gate driver 40B configured as disclosed in U.S. Patent Application Publication No. 2020/0135132.

As shown in FIG. 9, the liquid crystal display device 100A includes a display region DR defined by a plurality of pixels P and a non-display region FR located around the display region DR. Further, the liquid crystal display device 100A includes first and second gate drivers 40A and 40B that drive the gate bus lines GL(1) to GL(i) and a source driver 50 that drives the source bus lines SL(1) to SL(j).

The first gate driver 40A, the second gate driver 40B, and the source driver 50 are placed in the non-display region FR. The first gate driver 40A and the second gate driver 40B are GDM circuits. The first gate driver 40A is placed on the left side of the display region DR, and the second gate driver 40B is placed on the right side of the display region DR. That is, the first gate driver 40A and the second gate driver 40B are placed at first and second ends, respectively, of the gate bus lines GL(1) to GL(i).

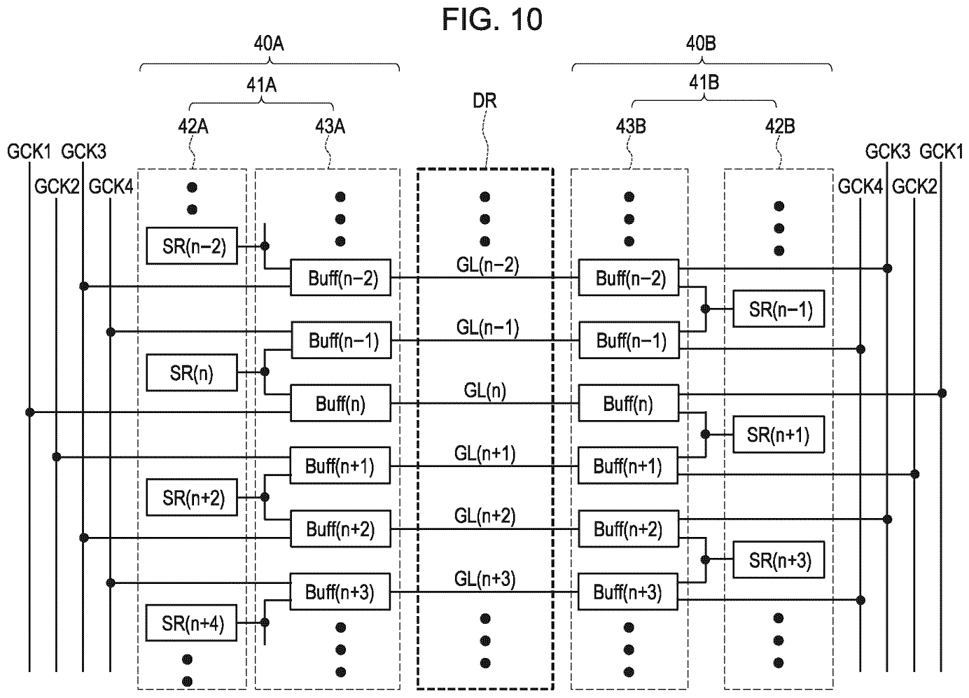

FIG. 10 is a diagram showing an overall configuration of the first gate driver 40A and the second gate driver 40B.

The first gate driver 40A and the second gate driver 40B each operate in accordance with a four-phase clock signal composed of a first gate clock signal GCK1, a second gate clock signal GCK2, a third gate clock signal GCK3, and a fourth gate clock signal GCK4.

The first gate driver 40A has a first shift register 41A including a first bistable circuit unit 42A and a first buffer circuit unit 43A. The first bistable circuit unit 42A has a plurality of bistable circuits SR (denoted as “ . . . , SR(n−2), SR(n), SR(n+2), SR(n+4), . . . ” in FIG. 10) arranged in a cascade connection. The first buffer circuit unit 43A has a plurality of buffer circuits Buff (denoted as “ . . . , Buff(n−2), Buff(n−1), Buff(n), Buff(n+1), Buff(n+2), Buff(n+3), . . . ” in FIG. 10).

The number of the plurality of bistable circuits SR of the first bistable circuit unit 42A is half (i.e. i/2) as large as the number i of pixel rows. On the other hand, the number of the plurality of buffer circuits Buff of the first buffer circuit unit 43A is equal (i.e. i) to the number i of pixel rows. Each bistable circuit SR of the first bistable circuit 42A corresponds to two buffer circuits Buff, and by supplying the two buffer circuits Buff with an output signal therefrom, the two buffer circuits Buff are controlled.

The second gate driver 40B has a second shift register 41B including a second bistable circuit unit 42B and a second buffer circuit unit 43B. The second bistable circuit unit 42B has a plurality of bistable circuits SR (denoted as “ . . . , SR(n−1), SR(n+1), SR(n+3), . . . ” in FIG. 10) arranged in a cascade connection. The second buffer circuit unit 43B has a plurality of buffer circuits Buff (denoted as “ . . . , Buff(n−2), Buff(n−1), Buff(n), Buff(n+1), Buff(n+2), Buff(n+3), . . . ” in FIG. 10).

The number of the plurality of bistable circuits SR of the second bistable circuit unit 42B is half (i.e. i/2) as large as the number i of pixel rows. On the other hand, the number of the plurality of buffer circuits Buff of the second buffer circuit unit 43B is equal (i.e. i) to the number i of pixel rows. Each bistable circuit SR of the second bistable circuit 42B corresponds to two buffer circuits Buff, and by supplying the two buffer circuits Buff with an output signal therefrom, the two buffer circuits Buff are controlled.

Since the first buffer circuit unit 43A of the first gate driver 40A and the second buffer circuit unit 43B of the second gate driver 40B each have as many buffer circuits Buff as the pixel rows, buffer circuits Buff are connected to both ends of each gate bus line GL. The first gate driver 40A and the second gate driver 40B are each supplied with a four-phase clock signal. Two buffer circuits Buff connected to an identical gate bus line GL are supplied with an identical gate clock signal. Each buffer circuit Buff receives an output signal from a corresponding one of the bistable circuits SR and a corresponding one of the gate clock signals and generates a scanning signal to be supplied to a corresponding one of the gate bus lines GL. For example, in the first buffer circuit unit 43A, the buffer circuit Buff(n) corresponding to the nth gate bus line GL(n) receives an output signal from the bistable circuit SR(n) and the first gate clock signal GCK1, generates a scanning signal, and supplies the scanning signal to the nth gate bus line GL(n). Further, the buffer circuit Buff(n−1) corresponding to the (n−1)th gate bus line GL(n−1) receives an output signal from the bistable circuit SR(n) and the fourth gate clock signal GCK4, generates a scanning signal, and supplies the scanning signal to the (n−1)th gate bus line GL(n−1).

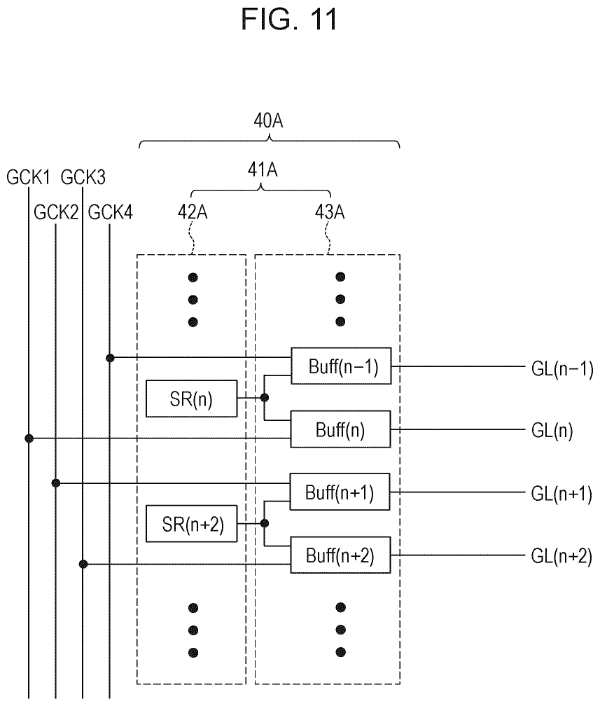

Next, the configurations of the gate drives are described in more detail by taking the first gate driver 40A as an example. FIG. 11 is a schematic circuit diagram showing a configuration of the first gate driver 40A.

The first bistable circuit unit 42A of the first gate driver 40A includes the bistable circuit SR(n) and SR(n+2) arranged in a cascade connection. An output end of the bistable circuit SR(n) is connected to an input end of the buffer circuit Buff(n−1) corresponding to the (n−1)th gate bus line GL(n−1) and an input end of the buffer circuit Buff(n) corresponding to the nth gate bus line GL(n). Further, an output end of the bistable circuit SR(n+2) is connected to an input end of the buffer circuit Buff(n+1) corresponding to the (n+1)th gate bus line GL(n+1) and an input end of the buffer circuit Buff(n+2) corresponding to the (n+2)th gate bus line GL(n+2). The buffer circuits Buff(n−1), Buff(n), Buff(n+1), and Buff(n+2) are supplied with the fourth gate clock signal GCK4, the first gate clock signal GCK1, the second gate clock signal GCK2, and the third gate clock signal GCK3, respectively.

In the example shown in FIG. 11, one bistable circuit SR and two buffer circuits Buff corresponding thereto constitute one unit circuit UC. The bistable circuit SR(n) and the buffer circuits Buff(n−1) and Buff(n) constitute one unit circuit UC, and the bistable circuit SR(n+2) and the buffer circuits Buff(n+1) and Buff(n+2) constitute another one unit circuit UC.

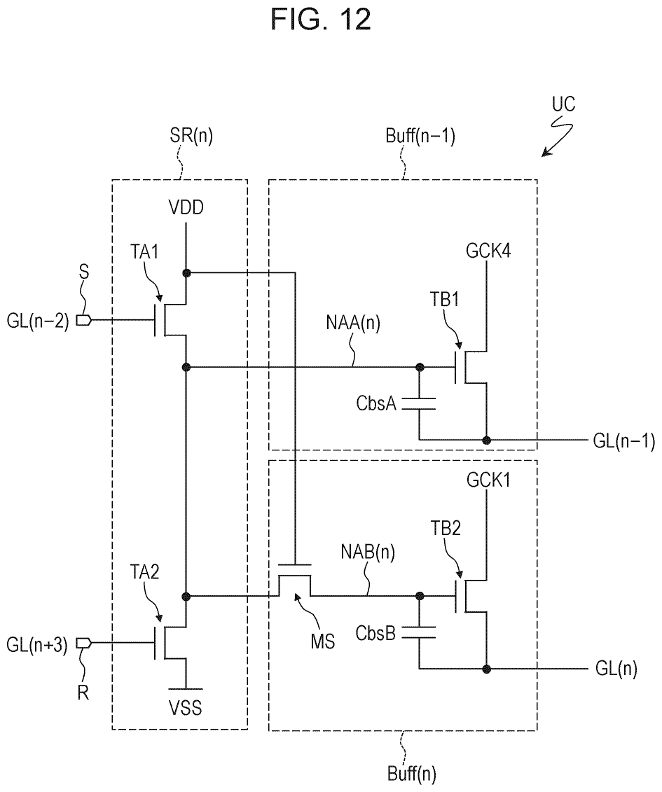

A basic configuration of each unit circuit US is described with reference to FIG. 12. FIG. 12 is a circuit diagram showing a basic configuration of a unit circuit UC including a bistable circuit SR(n). The unit circuit UC shown in FIG. 12 includes the bistable circuit SR(n) and buffer circuits Buff(n−1) and Buff(n).

The bistable circuit SR(n) includes two N-channel thin-film transistors TA1 and TA2. A drain terminal of the thin-film transistor TA1 is connected to a high-level power-supply line VDD, and a source terminal of the thin-film transistor TA2 is connected to a low-level power-supply line VSS. A source terminal of the thin-film transistor TA1 and a drain terminal of the thin-film transistor TA2 are connected to each other, and a point of connection between them is equivalent to the output terminal of the bistable circuit SR(n). A node NAA(n) including this output terminal is hereinafter called “first-state node”.

A gate terminal of the thin-film transistor TA1 is equivalent to a set terminal S, and a gate terminal of the thin-film transistor TA2 is equivalent to a reset terminal R. The set terminal S is connected to the (n−2)th gate bus line GL(n−2), and the reset terminal R is connected to the (n+3)th gate bus line GL(n+3).

The bistable circuit SR(n) is brought into a “set state” or a “reset state” by charging or discharging electric charge into or from a capacitor connected to the first-state node NAA(n). Specifically, in the presence of the application of a high-level voltage to the set terminal S, the bistable circuit SR(n) is brought into the “set state”, which is a state in which the first-state node NAA(n) carries a high-level voltage. Further, in the presence of the application of a high-level voltage to the reset terminal R, the bistable circuit SR(n) is brought into the “reset state”, which is a state in which the first-state node NAA(n) carries a low-level voltage. A high-level signal is outputted from the output terminal of the bistable circuit SR(n) when the bistable circuit SR(n) is in the “set state”.

The buffer circuit Buff(n−1) includes a buffer transistor TB1 and a boost capacitor CbsA. The buffer transistor TB1 is an N-channel thin-film transistor. A drain terminal of the buffer transistor TB1 is supplied with the fourth gate clock signal GCK4. A gate terminal of the buffer transistor TB1 is equivalent to an input terminal of the buffer circuit Buff(n−1) and is connected to the first-state node NAA(n). A source terminal of the buffer transistor TB1 is equivalent to an output terminal of the buffer circuit Buff(n−1) and is connected to the gate terminal of the buffer transistor TB1 via the boost capacitor CbsA and connected to the (n−1)th gate bus line GL(n−1).

The buffer circuit Buff(n) includes a buffer transistor TB2 and a boost capacitor CbsB. The buffer transistor TB2 is an N-channel thin-film transistor. The buffer circuit Buff(n) further includes an N-channel thin-film transistor MS. A drain terminal of the buffer transistor TB2 is supplied with the first gate clock signal GCK1. A gate terminal of the buffer transistor TB2 is connected to the first-state node NAA(n) via the thin-film transistor MS. Of conducting terminals of the thin-film transistor MS, a terminal connected to the first-state node NAA(n) is equivalent to an input terminal of the buffer circuit Buff(n). A source terminal of the buffer transistor TB2 is equivalent to an output terminal of the buffer circuit Buff(n) and is connected to the gate terminal of the buffer transistor TB2 via the boost capacitor CbsB and connected to the nth gate bus line GL(n).

A gate terminal of the thin-film transistor MS us connected to the high-level power-supply line VDD. A voltage of the high-level power-supply line VDD is hereinafter called “high-level power supply voltage” and denoted by the same reference sign “VDD”. Assuming that a threshold voltage of the thin-film transistor MS is Vth(MS), the thin-film transistor MS is in an off-state when both a source terminal and a drain terminal of the thin-film transistor MS carry voltages higher than VDD−Vth(MS).

Accordingly, even in the case of a rise in voltage of the gate terminal of the buffer transistor TB2 of the buffer circuit Buff(n) via the boost capacitor CbsB by a pulse of the first gate clock signal GCK1 at a time when the buffer transistor TB2 is in an on-state, that is, in voltage of a node (hereinafter called “second-state node”) NAB(n) including the gate terminal, the rise in voltage does not affect the voltage of the first-state node NAA(n). Further, even in the case of a rise in voltage of the gate terminal of the buffer transistor TB1 of the buffer circuit Buff(n−1) via the boost capacitor CbsA by a pulse of the fourth gate clock signal GCK4 at a time when the buffer transistor TB1 is in an on-state, that is, in voltage of the first-state node NAA(n), the rise in voltage does not affect the voltage of the second-state node NAB(n).

A reason for this is that based on the characteristics of the thin-film transistor MS as a field-effect transistor, the thin-film transistor MS operates as a transmission gate that transmits a voltage lower than or equal to VDD−Vth(MS) and that does not transmit a voltage exceeding VDD−Vth(MS). The thin-film transistor MS, which functions as such a transmission gate, functions such that a boost effect of one of the first-state node NAA(n) and the second-state node NAB(n) does not affect the other node. The thin-film transistor MS is hereinafter also called “boost separation transistor”.

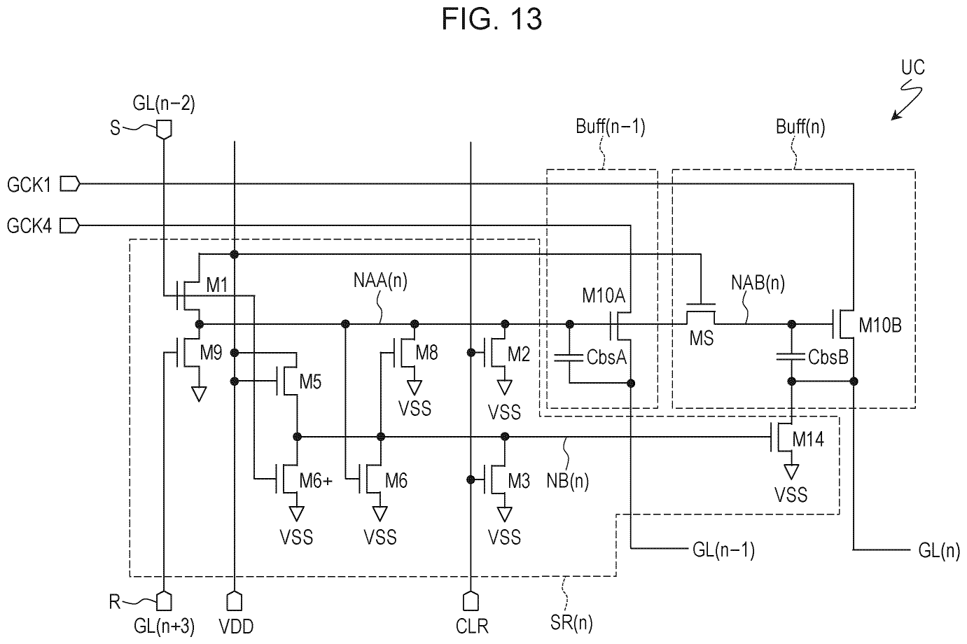

FIG. 13 is a circuit diagram showing a detailed example of a configuration of a unit circuit UC including a bistable circuit SR(n). In the example shown in FIG. 13, the bistable circuit SR(n) has N-channel thin-film transistors M1, M2, M3, M5, M6, M6+, M8, M9, and M14. The set terminal S is connected to the (n−2)the gate bus line GL(n−2), and the reset terminal R is connected to the (n+3)th gate bus line GL(n+3).

The thin-film transistors M1 and M9 are equivalent to the thin-film transistors TA1 and TA2 shown in FIG. 12, respectively. A point of connection between the thin-film transistors M1 and M9 constitutes an output terminal of the bistable circuit SR(n), and a node including this output terminal is a first-node NAA(n).

Further, the bistable circuit SR(n) has a clear terminal as an input terminal CLR for a clear signal for initialization, and gate terminals of the thin-film transistors M2 and M3 are connected to the clear terminal CLR. A node NB(n) including a point of connection between the thin-film transistors M5 and M6 is hereinafter called “third-state node”.

The buffer circuit Buff(n−1) has the same configuration as the buffer circuit Buff(n−1) shown in FIG. 12 and includes an N-channel thin-film transistor (buffer transistor) M10A and a boost capacitor CbsA. A drain terminal of the buffer transistor M10A is supplied with the fourth gate clock signal GCK4. A source terminal of the buffer transistor M10A is connected to the (n−1)th gate bus line GL(n−1).

The buffer circuit Buff(n) has the same configuration as the buffer circuit Buff(n) shown in FIG. 12 and includes an N-channel thin-film transistor (buffer transistor) M10B, an N-channel thin-film transistor (boost separation transistor) MS, and a boost capacitor CbsB. A drain terminal of the buffer transistor M10B is supplied with the first gate clock signal GCK1. A source terminal of the buffer transistor M10B is connected to the nth gate bus line GL(n). A gate terminal of the buffer transistor M10B is connected to the first-state node NAA(n) via the boost separation transistor MS, and a node including this gate terminal is a second-state node NAB(n).

A description of the operation of the gate drivers configured as illustrated here is omitted, as it is disclosed in U.S. Patent Application Publication No. 2020/0135132, the entire contents of which are hereby incorporated by reference.

### Example of Application of First TFT and Second TFT

An example of application of the aforementioned first and second TFTs to the unit circuit UC shown in FIG. 13 is described.

In the unit circuit UC shown in FIG. 13, one of a source terminal and a drain terminal of the thin-film transistor M1 is supplied with a high-level power supply voltage, and the other of the source terminal and the drain terminal of the thin-film transistor M1 is suppled with a low-level voltage in a large part of one frame. Further, a voltage exceeding a peak-to-peak voltage Vpp of a gate clock signal is applied between sources and drains of the thin-film transistors M2, M8, and M9.

Accordingly, the thin-film transistors M1, M2, M8, and M9 can be said to be circuit TFTs that need to be especially high in source-drain resistance (that is, that become especially high in strength of a drain-source electric field Eds during operation of the unit circuit UC).

Therefore, it is preferable that the thin-film transistors M1, M2, M8, and M9 be second TFTs.

### Regarding Oxide Semiconductor

An oxide semiconductor (also called “metallic oxide” or “oxide material”) contained in an oxide semiconductor layer of an oxide semiconductor TFT may be an amorphous oxide semiconductor or may be a crystalline oxide semiconductor having a crystalline portion. Examples of the crystalline oxide semiconductor include a polycrystalline oxide semiconductor, a microcrystal oxide semiconductor, and a crystalline oxide semiconductor whose c axis is oriented substantially perpendicular to a layer plane.

Materials, structures, and methods of formation of the amorphous oxide semiconductor and each of the foregoing crystalline oxide semiconductors, a configuration of an oxide semiconductor layer having a stack structure, or other features are described, for example, in Japanese Unexamined Patent Application Publication No. 2014-007399, the entire contents of which are hereby incorporated by reference.

The oxide semiconductor layer may contain, for example, at least one type of metallic element selected from among In, Ga, and Zn. In the present embodiment, the oxide semiconductor layer contains, for example, an In—Ga—Zn—O semiconductor (e.g. indium-gallium-zinc oxide). The In—Ga—Zn—O semiconductor here is a ternary oxide of In (indium), Ga (gallium), and Zn (zinc), and the proportions (composition ratios) of In, Ga, and Zn are not limited to particular proportions but include, for example, In:Ga:Zn=2:2:1, In:Ga:Zn=1:1:1, In:Ga:Zn=1:1:2, or other proportions. Such an oxide semiconductor layer can be formed from an oxide semiconductor film containing the In—Ga—Zn—O semiconductor.

The In—Ga—Zn—O semiconductor may be amorphous or may be crystalline. It is preferable that the crystalline In—Ga—Zn—O semiconductor be a crystalline In—Ga—Zn—O semiconductor whose c axis is oriented substantially perpendicular to a layer plane.

A crystal structure of the crystalline In—Ga—Zn—O semiconductor is disclosed, for example, in Japanese Unexamined Patent Application Publication No. 2014-007399, Japanese Unexamined Patent Application Publication No. 2012-134475, and Japanese Unexamined Patent Application Publication No. 2014-209727, the entire contents of which are hereby incorporated by reference. A TFT having an In—Ga—Zn—O semiconductor layer has high mobility (more than twenty times as high as that of an a-Si TFT) and a low leak current (less than 1/100 of that of an a-Si TFT) and, as such, is suitably used as a drive TFT (e.g. a TFT that is included in a drive circuit provided around a display region including a plurality of pixels and on top of the same substrate as the display region) and a pixel TFT (i.e. a TFT that is provided in a pixel).

The oxide semiconductor layer may contain another oxide semiconductor instead of the In—Ga—Zn—O semiconductor. For example, the oxide semiconductor layer may contain an In—Sn—Zn—O semiconductor (e.g. In₂O₃—SnO₂—ZnO; InSnZnO). The In—Sn—Zn—O semiconductor is a ternary oxide of In (indium), Sn (tin), and Zn (zinc). Alternatively, the oxide semiconductor layer may contain an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, a Cd—Pb—O semiconductor, CdO (cadmium oxide), a Mg—Zn—O semiconductor, an In—Ga—Sn—O semiconductor, an In—Ga—O semiconductor, a Zr—In—Zn—O semiconductor, a Hf—In—Zn—O semiconductor, an Al—Ga—Zn—O semiconductor, a Ga—Zn—O semiconductor, an In—Ga—Zn—Sn—O semiconductor, an In—W—Zn—O semiconductor.

An embodiment of the present disclosure makes it possible to provide an active matrix substrate that makes it possible to reduce characteristic degradation of an oxide semiconductor TFT in a gate drive circuit.

The present disclosure contains subject matter related to that disclosed in Japanese Priority Patent Application JP 2024-091803 filed in the Japan Patent Office on Jun. 5, 2024, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An active matrix substrate comprising:
a substrate;
a plurality of gate signal lines supported by the substrate; and
a gate drive circuit that drives the plurality of gate signal lines,
wherein
the gate drive circuit includes a shift register having a plurality of stages associated with the plurality of gate signal lines,
the plurality of stages are constituted by a plurality of unit circuits each including a plurality of oxide semiconductor TFTs,
the plurality of oxide semiconductor TFTs include
at least one first TFT each including a first oxide semiconductor layer, and
at least one second TFT each including a second oxide semiconductor layer and having lower mobility than does the at least one first TFT, and
the at least one second TFT includes, of the plurality of oxide semiconductor TFTs, an oxide semiconductor TFT that becomes highest in drain-source electric field strength during operation of each unit circuit.

2. The active matrix substrate according to claim 1, wherein
the at least one second TFT comprises n second TFTs, n being an integer greater than or equal to 2, and
the n second TFTs are oxide semiconductor TFTs that are first to nth highest in drain-source electric field strength during operation of each unit circuit when the plurality of oxide semiconductor TFTs are ranked according to the drain-source electric field strength.

3. The active matrix substrate according to claim 1, wherein
each of the at least one first TFT includes
the first oxide semiconductor layer including a first channel region and including a first source contact region and a first drain contact region that are located on both sides, respectively, of the first channel region, and
a first gate electrode placed over the first channel region of the first oxide semiconductor layer with the first gate insulating layer sandwiched between the first gate electrode and the first channel region, and
each of the at least one second TFT includes
the second oxide semiconductor layer including a second channel region and including a second source contact region and a second drain contact region that are located on both sides, respectively, of the second channel region, and
a second gate electrode placed over the second channel region of the second oxide semiconductor layer with the second gate insulating layer sandwiched between the second gate electrode and the second channel region.

4. The active matrix substrate according to claim 1, wherein
the second oxide semiconductor layer is formed at a layer different from that at which the first oxide semiconductor layer is formed, and
the second oxide semiconductor layer is lower in mobility than the first oxide semiconductor layer.

5. The active matrix substrate according to claim 4, wherein
the second gate insulating layer has a stack structure including a first insulating layer and a second insulating layer placed on top of the first insulating layer, and
the first gate insulating layer includes a third insulating layer formed at a layer identical to that at which the second insulating layer is formed, and does not include an insulating layer formed at a layer identical to that at which the first insulating layer is formed,
the active matrix substrate further comprising a lower insulating layer placed between the first oxide semiconductor layer and the substrate and formed at a layer identical to that at which the first insulating layer is formed.

6. The active matrix substrate according to claim 4, wherein
the first oxide semiconductor layer and the second oxide semiconductor layer each contain In and/or Sn, and
a sum of ratios of the numbers of atoms of In and Sn to those of all metallic elements in the second oxide semiconductor layer is smaller than a sum of ratios of the numbers of atoms of In and Sn to those of all metallic elements in the first oxide semiconductor layer.

7. The active matrix substrate according to claim 4, wherein
the first oxide semiconductor layer and the second oxide semiconductor layer each contain an In—Ga—Zn—O semiconductor, and
a ratio of the number of atoms of In to those of all metallic elements in the second oxide semiconductor layer is lower than a ratio of the number of atoms of In to those of all metallic elements in the first oxide semiconductor layer.

8. The active matrix substrate according to claim 1, wherein
the first oxide semiconductor layer has a stack structure including a lower oxide semiconductor layer and an upper oxide semiconductor layer, placed on top of the lower oxide semiconductor layer, that has lower mobility than does the lower oxide semiconductor layer, and
the second oxide semiconductor layer is formed at a layer identical to that at which the upper oxide semiconductor layer of the first oxide semiconductor layer is formed.

9. The active matrix substrate according to claim 8, wherein
the lower oxide semiconductor layer and the upper oxide semiconductor layer each contain In and/or Sn, and
a sum of ratios of the numbers of atoms of In and Sn to those of all metallic elements in the upper oxide semiconductor layer is smaller than a sum of ratios of the numbers of atoms of In and Sn to those of all metallic elements in the lower oxide semiconductor layer.

10. The active matrix substrate according to claim 8, wherein
the lower oxide semiconductor layer and the upper oxide semiconductor layer each contain an In—Ga—Zn—O semiconductor, and
a ratio of the number of atoms of In to those of all metallic elements in the upper oxide semiconductor layer is lower than a ratio of the number of atoms of In to those of all metallic elements in the lower oxide semiconductor layer.

11. The active matrix substrate according to claim 1, wherein the gate drive circuit is monolithically formed in the active matrix substrate.

12. A display device comprising the active matrix substrate according to claim 1.
